(19) United States
(12) Patent Application Publication
(10) Pub. No.: US 2021/0267085 A1
(43) Pub. Date: Aug. 26, 2021

(54) MODULAR EMBEDDED RACK CONTROL SYSTEM AND FRAMEWORK

(71) Applicant: Charles Jose Wigelsworth, Jacksonville, FL (US)

(72) Inventor: Charles Jose Wigelsworth, Jacksonville, FL (US)

(21) Appl. No.: 17/176,683

(22) Filed: Feb. 16, 2021

Related U.S. Application Data
(60) Provisional application No. 62/980,674, filed on Feb. 24, 2020.

(51) Int. Cl. H05K 7/18; A47B 87/02

(52) U.S. Cl. CPC H05K 7/18; A47B 87/0207

(57) ABSTRACT

A modular embedded rack control system and framework for rack mounting electronic modules in a stackable base unit block assembly that is a box-like structural frame structured as a two by three array whereby up to four internal panels mounted perpendicularly to and around a center front module rack can partition up to five vertical compartments. The standardized hardware framework includes a plurality of mountable external panel types, internal panel types, bus types, component types, and peripheral types that can be used to design and build a standalone system or system stack, or a networked node or node stack.

### CROSS-REFERENCE TO RELATED APPLICATIONS

This application claims benefit of U.S. Provisional Patent Application No. 62/980,674, filed Feb. 24, 2020, titled “MODULAR EMBEDDED RACK CONTROL SYSTEM AND FRAMEWORK”

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### TECHNICAL FIELD

The present invention is a foundational system and standardized hardware framework for broad and robust applications in consumer, business, industrial, and internet electronics and technology as a modular embedded rack control system that is stackable, repairable, and scalable.

### BACKGROUND OF THE INVENTION

Modern technological complexity, coupled with planned obsolescence models, has created a technological status quo where consumers face significantly higher and ever increasing costs to repair, if possible/feasible, or are forced to replace electronics and appliances. This dynamic has created numerous long-term societal and environmental impacts in the world. Movements such as “Right to Repair” have become increasingly common place and span the entire spectrum from consumer electronics and appliances to industrial systems. Planned obsolescence has also resulted in ever increasing amounts of electronic waste and pollution that damages the environment. There is a significant need in the world to address these problems on a systemic level via an anti-planned obsolescence paradigm shift in technology engineering and system design.

### SUMMARY OF THE INVENTION

In order to address the status quo problems caused by planned obsolescence models, the present invention seeks to provide a solution on the polar opposite paradigm of anti-planned obsolescence through a standardized hardware framework. The modular embedded rack control system and framework creates a foundation for this technology engineering and system design paradigm shift. This invention is a new system and framework utilizing many modular design abstractions bridging a broad spectrum of technologies and fields, including, but not limited to, a server rack, an industrial control panel, an industrial distribution panel, a desktop computer case, an electronics breadboard, and LEGOs. Using this new system and framework, technology and systems can be redesigned and optimized so that they are modular, durable, scalable, repairable, upgradeable, efficient (on cost and power), and repurposable, which addresses many problems in the world such as “Right to Repair” and numerous environmental consequences of planned obsolescence models.

### BRIEF DESCRIPTION OF THE DRAWINGS

FIG. 1A is a left/front external orthographic view of a block assembly in one embodiment of the present invention.

FIG. 1B is a right/back external orthographic view of a block assembly in one embodiment of the present invention.

FIG. 2 is an exploded orthographic view of a block assembly in one embodiment of the present invention.

FIG. 3 is a partial orthographic view of a block assembly with external panels removed in one embodiment of the present invention.

FIG. 4 is a partial orthographic view of a block assembly with external panels and modules/spacers removed in one embodiment of the present invention.

FIG. 5A is a partial left/front exploded orthographic view of modules/spacers in the block assembly rack in one embodiment of the present invention.

FIG. 5B is a partial right/back exploded orthographic view of modules/spacers in the block assembly rack in one embodiment of the present invention.

FIG. 6 is a partial top orthographic view of a block assembly with external panels removed showing the compartmental framework in one embodiment of the present invention.

### DETAILED DESCRIPTION OF THE INVENTION

The Figures represent one embodiment of the present invention, it is important to note that other variations and embodiments of the present invention are possible and are not to be construed as limitations of the spirit or scope of the present invention. The drawings illustrate one application of one embodiment of the present invention, a configurable high resolution pulse-width modulated motor control system, to provide context for the invention and broad application scope.

Reference Number Coding Format:
100 Block Assembly
110 Structural Frame
2XX External Panels
3XX Internal Panels
4XX Buses
5XX Modules
6XX Compartmental Framework

Framework Terminology:
The block assembly 100 is the base unit for the framework
A system is defined as an assembly of {1, . . . ,n} block assemblies 100 vertically stacked.
A system stack is defined as {2, . . . ,n} systems vertically stacked.
When a system is networked it is referred to as a node rather than a system
A node stack is defined as {2, . . . ,n} nodes vertically stacked.
A cluster is defined as a group of {2, . . . ,n} node stacks

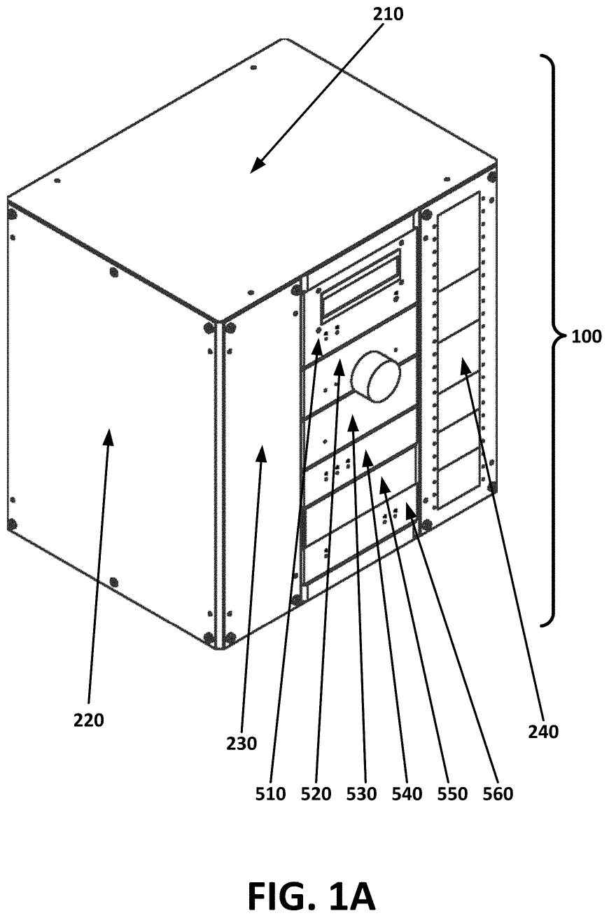

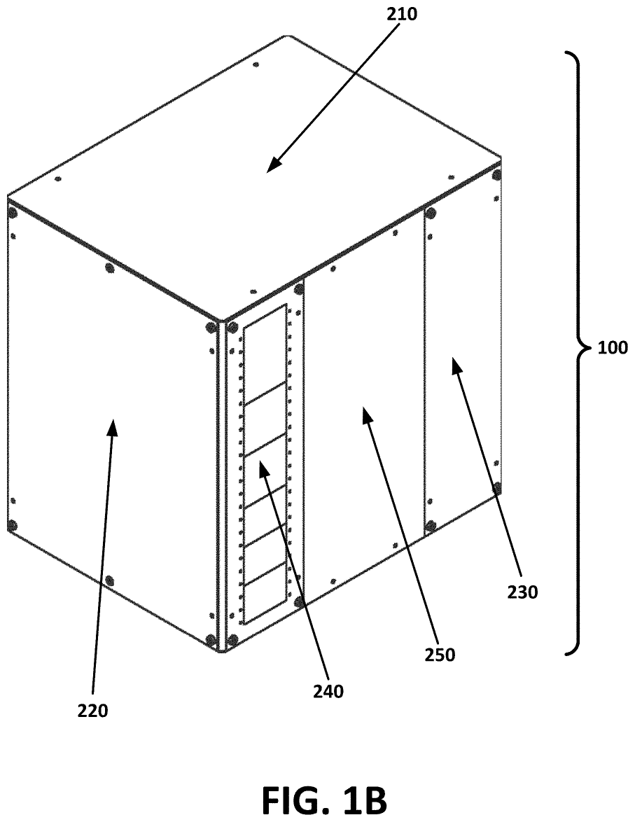

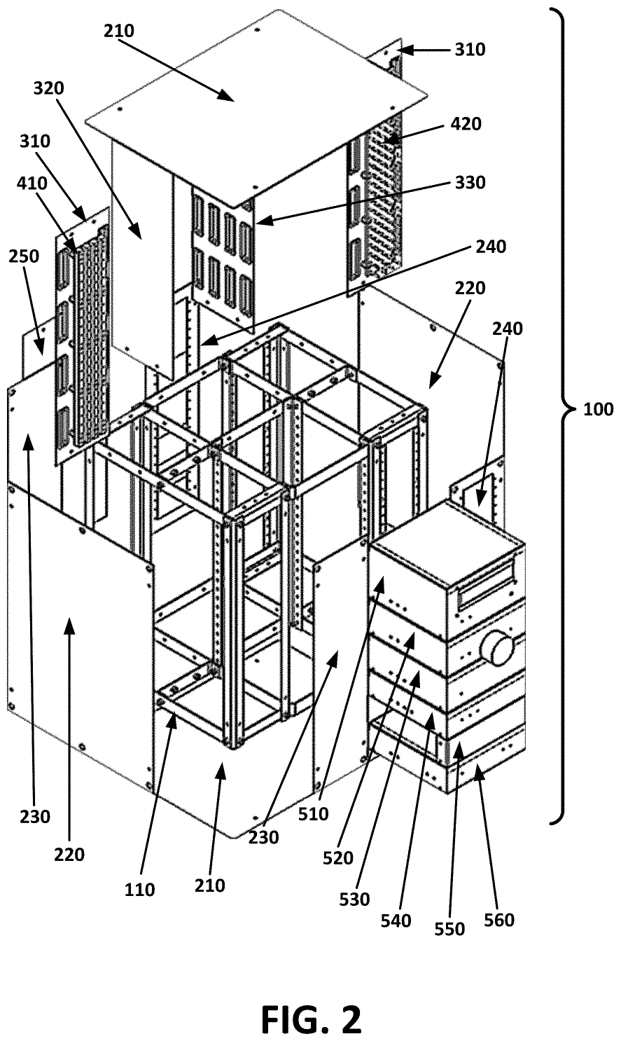

Referring to the Figures, FIG. 1A is a left/front external orthographic view of a block assembly 100 in one embodiment of the present invention and FIG. 1B is a right/back external orthographic view of the block assembly 100 seen in FIG. 1A. The external panels include: top external panel 210 as seen in FIG. 1A and FIG. 1B, bottom external panel 210 as seen in FIG. 2, left side solid external panel 220 as seen in FIG. 1A, right side solid external panel 220 as seen in FIG. 1B, solid front and back side panels 230 as seen in FIG. 1A and FIG. 1B, modular front and back side panels 240 as seen in FIG. 1A and FIG. 1B, and back center solid external panel 250 as seen in FIG. 1B. Modules/spacers as seen in FIG. 1A include: LCD module 510, rotary encoder module 520, microcontroller module 530, motor interface module 540, spacer 550, and 30 power supply module 560.

The block assembly 100 is designed to function as a standalone, self-contained system or node, or as a block in a system or node when there are two or more block assemblies 100 vertically stacked. The block assembly 100 as the base unit for the framework is key to maximizing economy of scale for manufacturing and systemic standardization. Vertical stacking allows significant modular 35 design and expansion dependent on application requirements. Vertical stacking can be used to expand a block assembly 100 that would require more modules than there is physical rack space for in a single block assembly 100 to build a larger system or node, or to combine systems or nodes into a stack for parallel or redundant applications. Vertical stacking can be achieved via numerous variations dependent on application requirements. The block assemblies 100 can bolted together to create a system by removing the top external panel 210 on the bottom block assembly 100, removing the bottom external panel 210 as seen in FIG. 2 on the top block assembly 100, and/or removing both top and bottom external panels 210 on in-between block assemblies 100, and bolting the structural frames 110 as seen in FIG. 2 together. Another variation is using a separate structural frame to rack mount the block assemblies 100 or systems/nodes themselves with or without the external panels 45 for easier removal to repair/upgrade, or they could be mounted externally/internally to numerous structural frameworks such as a wall, an appliance, an enclosure/panel, a chassis, or many other types of equipment/systems. Mounting hardware, including module rack mounting hardware and internal panels, can utilize many existing solutions as well, including but not limited to, server rack mounting hardware/methods, industrial control panel hardware/methods, or desktop computer case hardware/methods for the framework. Block assemblies 100 can be designed for various widths, lengths, and heights to accommodate wider/deeper modules and number depending on application requirements, standardized similar to rack unit sizing for example, but on a smaller scale. Block assemblies 100 can be designed with modular panels, modules, and structural frameworks for a broad spectrum of environmental conditions and factors, including but not limited to, particulates/dust, temperature, water, humidity, chemicals, vibration/shock, EMP, vacuum, pressure, and/or any combination thereof using best practices/methods such as seals, filters, heat sinks (internal and external), fans, and others. Another key design element in the block assembly 100 and its external facing components is the use of extensive functional color coding schemes and text/labeling for system/node stacks and clusters for robust system design, or just simply for aesthetic appeal and matching. For example, a node stack could use red for a stack power supply node, yellow for a battery backup node, blue for data node, green for a processing node, and orange for a networking node. Stack design allows for numerous methods of internal communication and networking across nodes within a stack with each other, or external communication and networking between other nodes and/or node stacks.

External panels include, but are not limited to, several design variations such solid, windowed, air flow, filtering, seals, and/or modular panels. Modular front and back side panels 240 as seen in FIG. 1A and FIG. 1B are designed to be coupled with modules and extend their interface capability in cases where there is either insufficient space on the front of the module or additional input/output routing to panel mount components on either the front or back of the block assembly 100 from the module is required. In addition to routing input/output power and signal connectors/ports, the panel mount components could also include various human-machine interface components such as diagnostic indicators, LCDs, buttons, keypads, switches, sensors, mini drive/component bays and many others. It's also possible that a small, slim vertically mounted module or printed circuit board (henceforth referred to as PCB(s)) could be mounted on the back of the modular panel slats for more complex panel mount component expansion. Any of the other variations in external panels could also be designed to incorporate panel mount components as well if required for an application. Modules include, but are not limited to, several design variations on both the module enclosure and the PCBs inside. Modules are designed to maximize the modularity of system designs while maintaining repairability and interchangeability between systems, that is, one module design could be used across multiple applications/systems/nodes or used to repair/replace a module across systems/nodes. This design approach allows for fast, easy repair and maintenance of systems/nodes, which also maximizes reusability of components and increases the residual value of systems/nodes. Additionally, module designs can be designed to maximize efficiency in circuit design, power usage, and many other factors which minimizes the need to redesign a specific module design across applications and can standardize a broad spectrum of common modules and circuits. Module circuit complexity can vary widely depending on application, but they can cover a broad design spectrum from simple to complex. Because of the rack mounted nature of the modules in the block assembly 100, modules can also be used standalone for bench development and rapid prototyping, and subsequently placed into a block assembly 100 drastically reducing system/node development time and cost. In the preferred embodiment, modules are designed to house PCBs and stacks thereof with a width of 100 mm and a depth of 100 mm with variable height to match rack mount spacing in the block assembly 100.

Module enclosure design variation can also cover a broad spectrum depending on environmental conditions as outlined previously for the block assembly 100. The preferred embodiment for general application is a module enclosure that has removable/replaceable external module panels/covers and an internal module enclosure frame, similar to an industrial NUC style computer enclosure with more modularity in module panels. This design approach means that the module enclosure panels can easily be removed/replaced for any number of module design applications, color coding schemes, text/labeling, pinouts, connectors/ports, internal module panel mount components, PCB mounted components, and other factors. By standardizing an internal frame that can be reused 100 across modules and only designing/customizing different module enclosure external panels, the design allows for robust, high efficiency manufacturing, reduced costs, and waste minimization. Like the block assembly 100, extensive color coding and text/labeling schemes are possible for the module enclosures themselves. Modules consist of four usable sides: front, left, right, and back. The front side of a module is used for various diagnostic indicators/lights, panel mount components, and other interface requirements. The rotary encoder module 520 reflects this front side design approach which includes diagnostic indicators for power, switch LED, and channel A and B indicators for a switched quadrature rotary encoder. The LCD module 510 provides a LCD interface for providing user information such as duty cycle and motor RPM from tachometer, as well as a user configurable interface for the pulse-width modulation settings like frequency, tach poles, number of encoder positions, and other settings in addition to speed control. Both modules are standardized and can be used in any number of other systems that would require those systemic functions. The left side panel (as viewed from the front) on modules would be reserved for power and ground input to the module or output to the power bus, while the right side panel on modules is used for input/output to external connectors/ports/panel mount components/external power output on the front and/or back right side panels on the block assembly 100, routing internal system/node or stack internal communications on signal buses, or both. The back panel on the module is used for internal connections between modules. The microcontroller module 530 back panel provides access to most or all of the microcontroller pins/ports for general purpose input/output or peripherals, and perhaps excluding any pins required for programming/debugging. In the preferred embodiment, a microcontroller, microprocessor, FPGA, or other type of processors will use internal peripheral routing and port mapping to maximize the modularity, standardization, and reusablity of processor modules with the back connectors. A microcontroller module 530 could be used in numerous systems without any internal hardware changes, only a firmware change to reroute peripherals, ports, and/or external wires.

PCB layout variation within module enclosures will generally follow four primary layouts: single horizontal PCB, vertically stacked horizontal PCBs like the modules or a PCB shield type layout, using a bottom horizontal backplane with vertically attached PCBs into slots or other edge connectors/pins like a desktop computer motherboard and peripheral cards, or using a single panel mounted vertical backplane with horizontally attachecd PCBs into slots or other edge connectors/pins. Because systems will be standardized on smaller scale rack unit system for width and depth, stackable PCBs within a module enclosure allow the module enclosure height to incorporate higher complexity modules into the framework while maintaining modularity and repairability, limited only by the mountable rack height within a block assembly 100. PCBs themselves could also be designed in such a way that they could incorporate single component microboards, component sized socketable, dip, header, or screw in boards, for easy repair/replacement of failed components minimizing the need to desolder failing/failed components and resoldering new ones.

In order to maximize modularity, repairability, and interchangeability within the framework, wires, cables, and connectors are integral components to the design. Wires and cables tie not only modules together, but connect the modules to power and signal buses, wires, cables, ports, connectors, and other components and any external panel mount components. The importance of block assembly 100 and module color coding and text/labeling schemes can be extended to wires, cables, and connectors to help further standardize the framework. Connectors themselves can vary wildly depending on application requirements, but could use any existing or future connector designs as needed within the system, such as USB, HDMI, ethernet, serial, and many others across any number of industries. Although the preferred embodiment would use standardized connectors whenever required, for simple point-to-point wiring between modules the preferred embodiment would use banana/bullet and screw-on banana/bullet type plugs and jacks that are often found in radio-control (RC) and audio applications. Additionally, the system can utilize any existing or future connector converters.

Referring to the Figures, FIG. 2 is an exploded orthographic view of a block assembly in one embodiment of the present invention. The exploded view reveals three additional framework components not visible externally as in FIG. 1A and FIG. 1B: structural frame 110, internal panels, and buses. The internal panels include: mountable internal panel with side wire/cable grommets 310, solid internal panel 320, and wire/cable grommet panel 330. The buses include: copper bar power bus 410 and signal bus PCB 420.

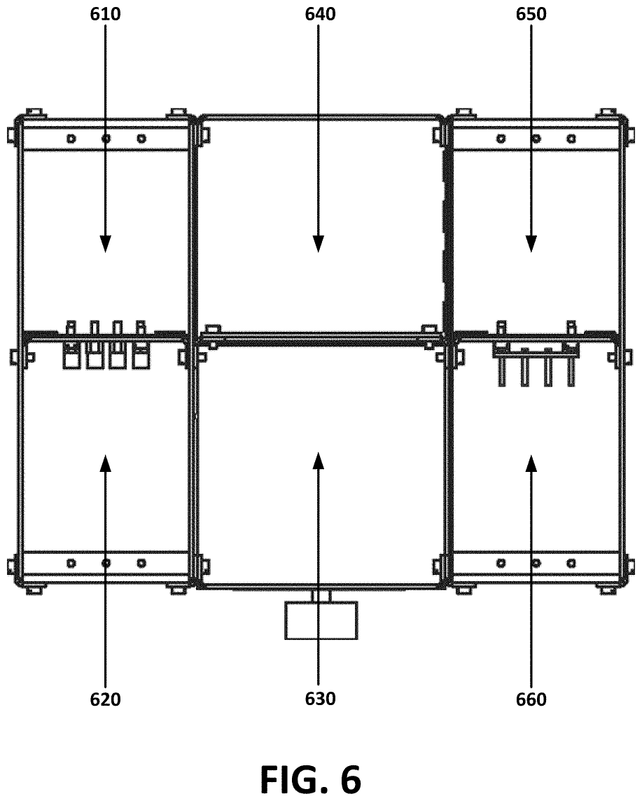

The structural frame 110 design variations can include any best practices, methods, materials, or hardware scaled for use in a block assembly 100, system/node, or system stack/node stack such as seen in desktop computer cases, server racks, industrial control panels, or any other electrical panel/enclosure following the compartmental framework as seen in FIG. 6.

The internal panels mark the boundaries for the internal compartmental framework as seen in FIG. 6 of the block assembly 100. The interchangeable modular design allows them to be selected, removed, or replaced depending on application requirements. The mountable internal panel with side wire/cable grommets 310 is designed to allow different types of hardware such as PCBs, copper bus bars, or other slim passive or active components such as a slim ethernet switch to be mounted onto the internal panel. Signal bus PCBs can be designed for any existing protocols such as CANBus, ethernet, SPI, UART, I2C, and any future protocols. For systems/nodes that require extensive communications internally or externally, the block assembly 100 can support up to three signal bus internal panels with one internal panel reserved for power distribution. Alternatively, a system can also route power to other internal panel buses, or any combination thereof. Another benefit of this modular approach is that PCBs, buses, and other mountable components can be designed to have modular connectors in order to minimize waste in having too many connectors that are not required for an application. In a system/node or system stack/node stack, the buses are designed to jump/shunt from block assembly 100 to block assembly 100 in order to distribute power or signals across an entire system, node, or stack thereof. The wire/cable grommet panel 330 is designed to maximize organization for cable management and routing as required for an application. As with the rest of the framework, internal panels and mounted components can utilize extensive color coding and text/labeling schemes.

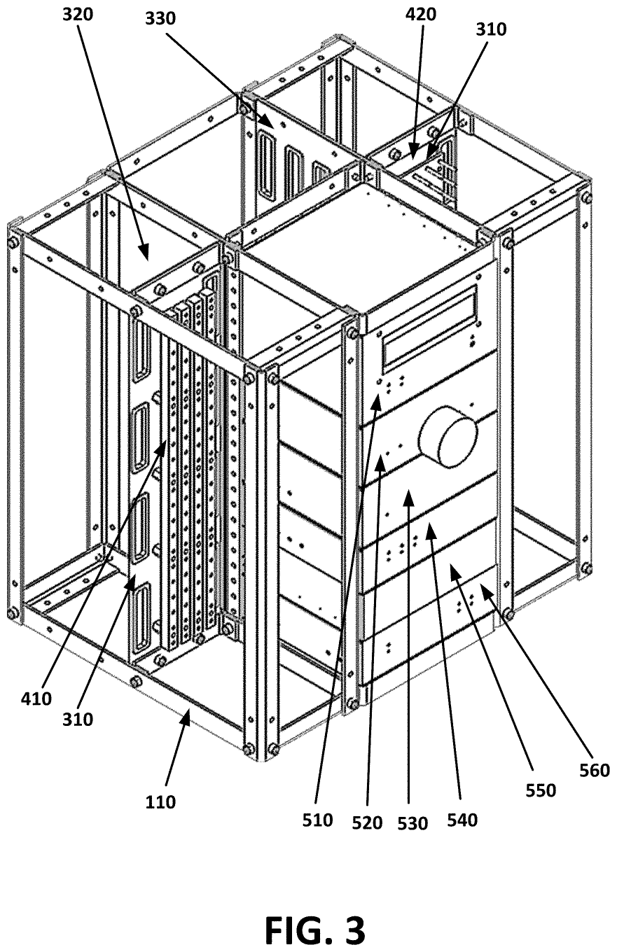

Referring to the Figures, FIG. 3 is a partial orthographic view of a block assembly with external panels removed in one embodiment of the present invention. FIG. 3 shows how the structural frame 110, modules, internal panels, and buses are assembled within the block assembly 100.

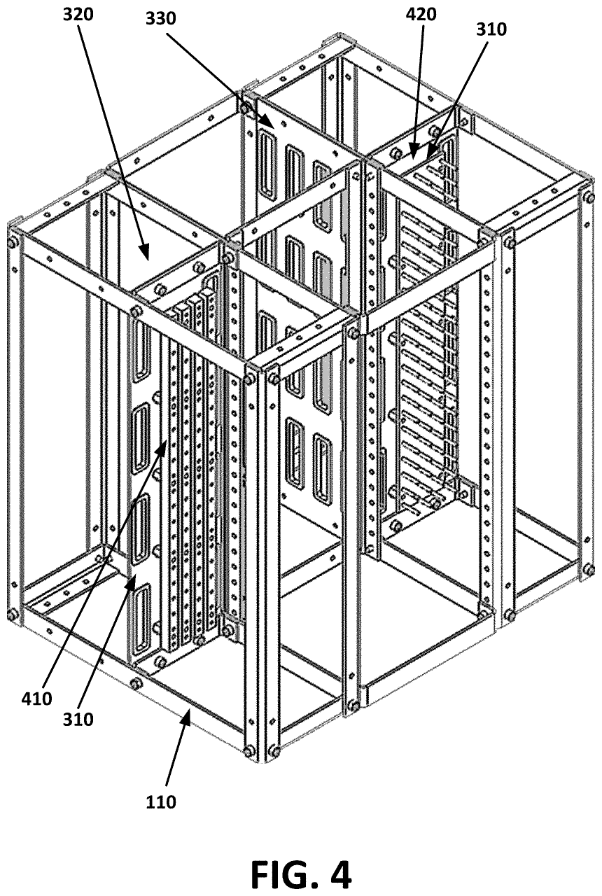

Referring to the Figures, FIG. 4 is a partial orthographic view of a block assembly with external panels and modules/spacers removed in one embodiment of the present invention. FIG. 4 shows how the structural frame 110, internal panels, and buses are assembled within the block assembly 100.

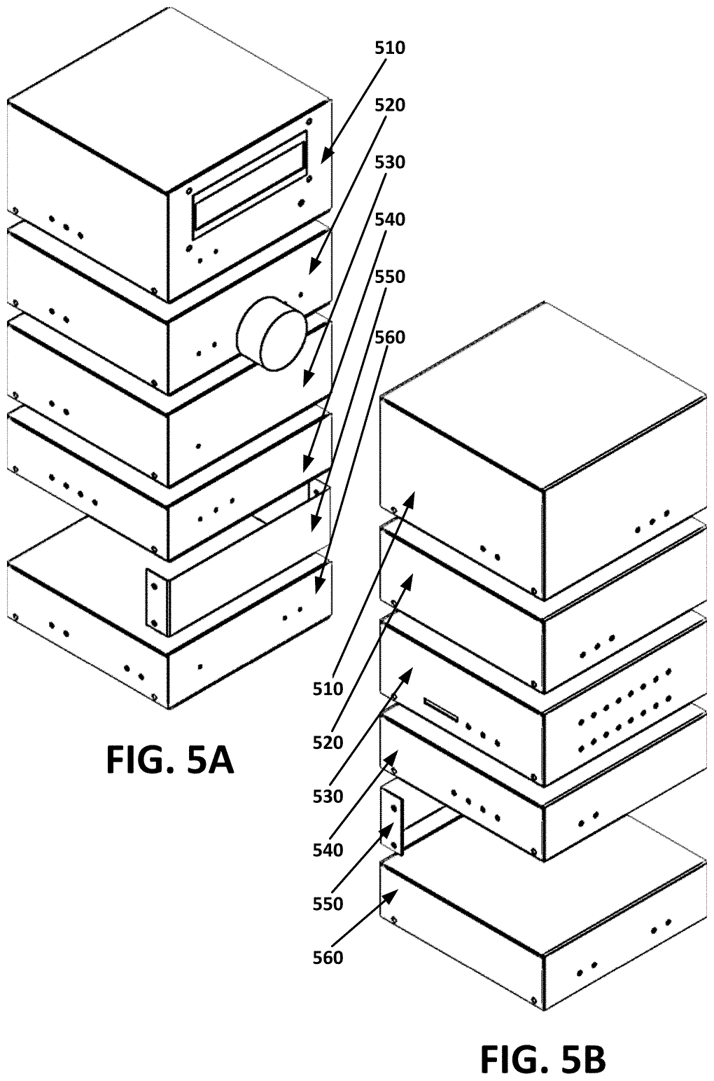

Referring to the Figures, FIG. 5A is a partial left/front exploded orthographic view of modules/spacers in the block assembly rack and FIG. 5B is a partial right/back exploded orthographic view of modules/spacers in the block assembly rack in one embodiment of the present invention.

Referring to the Figures, FIG. 6 is a partial top orthographic view of a block assembly 100 with external panels removed showing the compartmental framework in one embodiment of the present invention. Each block assembly 100 is subdivided into six compartments: power compartment 610, power distribution/bus compartment 620, module rack compartment 630, module wiring/cabling compartment 640, external ports/panel mount components and/or additional system, node, stack wiring/cabling compartment 650, and signal bus and/or external ports/panel mount components compartment 660.

The modular design of the block assembly 100 allows for significant variation of compartmental uses dependent on application requirements. In the preferred embodiment, power compartment 610 is used to contain any power transformers required for a system, node, or stack and any external power ports/switches/other panel mount components. The compartment is also large enough to potentially house redundant power transformers and/or uninterruptable power supply/battery back-ups for a block/system/node/stack. The power compartment 610 could also utilize a modular back side panel 240 to make these power components mounted in bays for easy removal/replacement as needed. Power, power switches, and other power control options could also be routed to a modular front side panel 240 through the internal panel for applications where it is more convenient to have them on the front rather than the back. The power distribution/bus compartment 620 will provide power distribution as required for all the modules in the rack mount, as well as being able to route power through other internal panels to the other side of the block assembly 100 as may be needed for an application. The module rack compartment 630 holds the modules which are loaded from the front of the system. The module wiring/cabling compartment 640 is where modules are interconnected for signals. The external ports/panel mount components and/or additional system, node, stack wiring/cabling compartment 650 would be primarily used for any additional cable routing a system/node stack would require where a jumped/shunted bus is insufficient or not ideal for a particular application in the preferred embodiment of the invention. It could also serve to house various network type components/ports/connectors in a node stack or cluster application. The signal bus and/or external ports/panel mount components compartment 660 will have significant variation in use depending on whether or not signals are more conveniently routed on the right of the block assembly 100 or in the module wiring/cabling compartment 640 with signal buses on those internal panels. Variation can be attributed to a networked node/node stack having different requirements than a system/system stack.

I claim:

1. A modular embedded rack control system and framework wherein the stackable base unit is a block assembly comprising:
a box-like structural frame structured as a two by three array whereby up to four internal panels mounted perpendicularly to and around a center front module rack can partition up to five vertical compartments;
a plurality of external panel types that can mounted to the structural frame;
a plurality of internal panel types that can be mounted to the structural frame;
a plurality of bus types that can be mounted to an internal panel or panels;
a plurality of component and peripheral types that can be mounted to internal and external panels;
a plurality of compartmental component and peripheral types that can be mounted within the structural frame;
a plurality of rack mountable spacer types;
a plurality of rack mountable modules and module types.

2. A modular embedded rack control system and framework as defined in claim 1 that can function as a standalone system or system stack, or as a networked node or node stack, and can themselves be mounted or racked.
